(19) United States
(12) Patent Application Publication
(10) Pub. No.: US 2026/0246472 A1
(43) Pub. Date: Aug. 20, 2026

(54) PHASE-LOCKED LOOP AND OPERATING METHOD OF THE PHASE-LOCKED LOOP

(71) Applicant: SK hynix Inc., Gyeonggi-do (KR)

(72) Inventor: Jae Min SHIM, Gyeonggi-do (KR)

(21) Appl. No.: 19/256,161

(22) Filed: Jul. 1, 2025

(30) Foreign Application Priority Data
Feb. 14, 2025 (KR) 10-2025-0019191

(51) Int. Cl. H03L 7/089; H03L 7/087; H03L 7/093

(52) U.S. Cl. CPC H03L 7/0891; H03L 7/087; H03L 7/093

(57) ABSTRACT

A phase-locked loop includes a phase detection circuit configured to detect a difference between phases of a first clock and a second clock, a charge pumping circuit configured to perform a charge pumping operation based on an output signal of the phase detection circuit to generate a control voltage, a voltage generation circuit configured to buffer the control voltage to generate an operating voltage, and configured to vary a level of the operating voltage in proportion to changes in a level of the control voltage and an amount of a control current, an oscillating circuit configured to generate the second clock that toggles at a frequency corresponding to the level of the operating voltage, and a size adjustment circuit configured to adjust the amount of the control current to maintain the level of the control voltage within a range between a set first level and a set second level.

### CROSS-REFERENCE TO RELATED APPLICATION

This application claims priority under 35 U.S.C. § 119(a) to Korean Patent Application No. 10-2025-0019191, filed on Feb. 14, 2025, the entire contents of which are incorporated herein by reference.

### BACKGROUND

### 1. Field

Embodiments relate to a semiconductor technology, and particularly, to a phase-locked loop and an operating method of a phase-locked loop.

### 2. Discussion of the Related Art

A phase-locked loop (PLL) is a circuit for performing a locking operation of comparing a phase of an external clock input from an exterior with a phase of an internal clock generated therein, changing a frequency of the internal clock according to the comparison result, and synchronizing the phase of the external clock with the phase of the internal clock. The phase-locked loop is one of basic (or core) circuits generally provided in an integrated circuit such as a semiconductor device.

When a phase difference between an external clock and an internal clock is equal to or less than a phase difference defined in advance by a plurality of delay cells, a general phase-locked loop determines that the phases of the external clock and the internal clock have been synchronized with each other and thereby determines locking completion.

In the phase-locked loop using a voltage-controlled oscillating method, in order to widely secure the generation frequency range of an internal clock, it is necessary to widely secure the range of a change in the level of a control voltage. However, in general, when considering that the control voltage is generated through charge pumping, if the range of a change in the level of the control voltage is blindly widely secured, an operation of the phase-locked loop may become unstable because a voltage ripple phenomenon occurs.

### SUMMARY

Various embodiments are directed to providing a phase-locked loop using the voltage-controlled oscillating method, which can widely secure the frequency of an internal clock while maintaining a change in the level of a control voltage within a set level range, and an operating method of the phase-locked loop.

The problems to be solved by the present disclosure are not limited to the above-mentioned problems, and the other unmentioned problems will be clearly understood from the following description by those skilled in the art.

An aspect of an embodiment in the invention, a phase-locked loop may include: a phase detection circuit configured to detect a difference between phases of a first clock and a second clock; a charge pumping circuit configured to perform a charge pumping operation based on an output signal of the phase detection circuit to generate a control voltage; a voltage generation circuit configured to buffer the control voltage to generate an operating voltage, and configured to vary a level of the operating voltage in proportion to changes in a level of the control voltage and an amount of a control current; an oscillating circuit configured to generate the second clock that toggles at a frequency corresponding to the level of the operating voltage; and a size adjustment circuit configured to adjust the amount of the control current to maintain the level of the control voltage within a range between a set first level and a set second level.

An aspect of an embodiment in the invention, an operating method of a phase-locked loop, the operating method may include: detecting a difference between phases of a first clock and a second clock to generate a detection signal; performing a charge pumping operation in response to the detection signal to generate a control voltage; generating an operating voltage having a level that varies in proportion to changes in a level of the control voltage and an amount of a control current; generating the second clock that toggles at a frequency corresponding to the level of the operating voltage; and adjusting the amount of the control current to maintain the level of the control voltage within a range between a set first level and a set second level.

According to embodiments of the present disclosure, in order to widely secure the frequency of an internal clock in the phase-locked loop using a voltage-controlled oscillating method, when a change in the level of the control voltage exceeds a set level range, the amount of a current that is supplied for buffering is adjusted in a process of the control voltage being transmitted to the oscillator. Accordingly, a change in the level of the control voltage can be moved within the set level range, and the frequency of the internal clock generated by the oscillator can also be stably maintained.

Accordingly, a change in the level of the control voltage can be maintained within the set level range, and the frequency of the internal clock can also be widely secured.

As described above, the jitter characteristic of the internal clock can be prevented from being degraded by minimizing the occurrence of a voltage ripple phenomenon in a charge pumping process because the range of a change in the level of the control voltage that is generated through charge pumping can be maintained within a set level range.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a block diagram illustrating a configuration of a phase-locked loop according to an embodiment of the present disclosure.

FIG. 2 is a block diagram illustrating a detailed configuration of a size adjustment unit illustrated in FIG. 1, according to an embodiment of the present disclosure.

FIGS. 3A to 3D are circuit diagrams for describing a detailed configuration and an operation of a voltage generation unit illustrated in FIG. 1, according to an embodiment of the present disclosure.

FIG. 4 is a circuit diagram illustrating a detailed configuration of an operation controller illustrated in FIG. 2, according to an embodiment of the present disclosure.

FIG. 5 is a circuit diagram illustrating a detailed configuration of a signal generation unit illustrated in FIG. 2, according to an embodiment of the present disclosure.

FIGS. 6A to 6C are waveform diagrams for describing an operation of the phase-locked loop, according to an embodiment of the present disclosure.

### DETAILED DESCRIPTION

Various embodiments of the present disclosure are described below with reference to the accompanying drawings. Elements and features of the disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated). The block/unit/circuit/component used with the “configured to” language includes hardware-for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that implement or perform one or more tasks.

As used in the disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or a portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that the terms precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. For example, the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

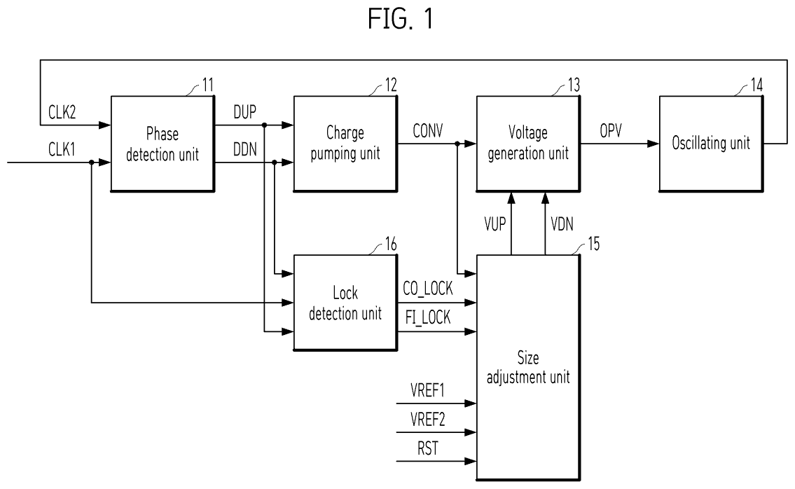

FIG. 1 is a block diagram illustrating a configuration of a phase-locked loop in accordance with an embodiment of the present disclosure.

Referring to FIG. 1, an example of the phase-locked loop in accordance with the embodiment of the present disclosure may include a phase detection unit (i.e., a phase detection circuit) 11, a charge pumping unit (i.e., a charge pumping circuit) 12, a voltage generation unit (i.e., a voltage generation circuit) 13, an oscillating unit (i.e., an oscillating circuit) 14, a size adjustment unit (i.e., a size adjustment circuit) 15, and a lock detection unit 16.

The phase detection unit 11 may detect a phase difference between a first clock CLK1 and a second clock CLK2. The first clock CLK1 may be a clock input from the outside of the phase detection unit 11. Furthermore, a second clock CLK2 may be an internal clock that is generated and fed back by the oscillating unit 14.

The charge pumping unit 12 may generate a control voltage CONV by performing a charge pumping operation according to output signals DUP and DDN of the phase detection unit 11.

According to an embodiment, when the phase of the second clock CLK2 is behind the phase of the first clock CLK1, the phase detection unit 11 may activate a first signal DUP and deactivate a second signal DDN. In this instance, the voltage generation unit 13 may increase the level of the control voltage CONV beyond a current level. For example, when the level of the control voltage CONV currently being generated is 300 mV, the voltage generation unit 13 may increase the level of the control voltage CONV to 320 mV in response to the activation state of the first signal DUP and the deactivation state of the second signal DDN.

According to another embodiment, when the phase of the second clock CLK2 is ahead of the phase of the first clock CLK1, the phase detection unit 11 may deactivate the first signal DUP and activate the second signal DDN. In this instance, the voltage generation unit 13 may decrease the level of the control voltage CONV beyond the current level. For example, when the level of the control voltage CONV currently being generated is 300 mV, the voltage generation unit 13 may decrease the level of the control voltage CONV to 280 mV in response to the deactivation state of the first signal DUP and the activation state of the second signal DDN.

Furthermore, the voltage generation unit 13 may generate an operating voltage OPV by buffering the control voltage CONV generated by the charge pumping unit 12. In this instance, the voltage generation unit 13 may vary the level of the operating voltage OPV in proportion to changes in the level of the control voltage CONV and the amount of a control current CONI.

According to an embodiment, assuming that the amount of the control current is the same, the voltage generation unit 13 may raise the level of the operating voltage OPV in response to the level of the control voltage CONV rising. In contrast, assuming that the amount of the control current is the same, the voltage generation unit 13 may lower the level of the operating voltage OPV in response to the level of the control voltage CONV falling.

According to another embodiment, assuming that the level of the control voltage CONV is the same, the voltage generation unit 13 may increase the level of the operating voltage OPV in response to the amount of the control current being increased. In contrast, assuming that the level of the control voltage CONV is the same, the voltage generation unit 13 may decrease the level of the operating voltage OPV in response to the amount of the control current being decreased.

Furthermore, the oscillating unit 14 may generate the second clock CLK2 that toggles in a frequency corresponding to the level of the operating voltage OPV.

According to an embodiment, the oscillating unit 14 may generate the second clock CLK2 having a toggling frequency increased in proportion to the level of the operating voltage OPV.

Furthermore, the size adjustment unit 15 may adjust the amount of the control current in order to maintain the level of the control voltage CONV generated by the charge pumping unit 12 within a range between a set first level and a set second level. In this case, the first level may be a higher voltage level than the second level. That is, the size adjustment unit 15 may compare the level of the control voltage CONV with each of a first reference voltage VREF1 having a level set as the first level and a second reference voltage VREF2 having a level set as the second level.

Furthermore, the size adjustment unit 15 may generate current adjustment signals VUP and VDN in order to adjust the control current, and may transmit the current adjustment signals VUP and VDN to the voltage generation unit 13.

According to an embodiment, the size adjustment unit 15 may change the amount of the control current in a default fluctuation DEFAULT when the level of the control voltage CONV varies during an interval between the first level or less and the second level or more. In this instance, the amount of the control current varying in the default fluctuation may mean that the level of the operating voltage OPV varies in a default interval in accordance with a change in the level of the control voltage CONV during an interval between the first level or less and the second level or more.

According to another embodiment, when the level of the control voltage CONV is placed in an interval in which the level of the control voltage CONV is higher than the first level, the size adjustment unit 15 may change the amount of the control current in a down fluctuation relatively smaller than the default fluctuation. In this instance, the amount of the control current being changed in the down fluctuation may mean that the level of the operating voltage OPV varies in the default interval in accordance with a change in the level of the control voltage CONV during an interval in which the level of the control voltage CONV is higher than the first level. That is, the size adjustment unit 15 may change the level of the operating voltage OPV in the default interval by controlling the amount of the control current to vary in the down fluctuation although the control voltage CONV is in the state in which the level of the control voltage CONV is placed in the interval in which the level of the control voltage CONV is higher than the first level. As described above, if the level of the operating voltage OPV is changed in the default interval during the interval in which the level of the control voltage CONV is higher than the first level due to an operation of the size adjustment unit 15, as a phase-locked loop operation through the oscillating unit 14, the phase detection unit 11, the charge pumping unit 12, and the voltage generation unit 13 is repeated, the level of the control voltage CONV may drop to the first level or less.

According to still another embodiment, when the level of the control voltage CONV is placed in an interval in which the level of the control voltage CONV is less than the second level, the size adjustment unit 15 may change the amount of the control current in an up fluctuation relatively greater than the default fluctuation. In this case, the amount of the control current being changed in the up fluctuation may mean that the level of the operating voltage OPV varies in the default interval in accordance with a change in the level of the control voltage CONV during the interval in which the level of the control voltage CONV is less than the second level. That is, the size adjustment unit 15 may change the level of the operating voltage OPV in the default interval by controlling the amount of the control current to vary in the up fluctuation although the control voltage CONV is in the state in which the level of the control voltage CONV is placed in the interval in which the level of the control voltage CONV is less than the second level. As described above, if the level of the operating voltage OPV varies in the default interval even during the interval in which the level of the control voltage CONV is less than the second level due to an operation of the size adjustment unit 15, as a phase-locked loop operation through the oscillating unit 14, the phase detection unit 11, the charge pumping unit 12, and the voltage generation unit 13 is repeated, the level of the control voltage CONV may rise to the second level or more.

Furthermore, a lock detection unit 16 may activate the coarse lock signal CO_LOCK when a difference between the phases of the first clock CLK1 and the second clock CLK2 is detected as being a coarse phase difference or less in response to the output signals DUP and DDN of the phase detection unit 11. Furthermore, the lock detection unit 16 may activate the fine lock signal FI_LOCK when a difference between the phases of the first clock CLK1 and the second clock CLK2 is detected as being a fine phase difference or less, which is smaller than the coarse phase difference in response to the output signals DUP and DDN of the phase detection unit 11. That is, the coarse lock signal CO_LOCK may always be activated earlier than the fine lock signal FI_LOCK.

Furthermore, the size adjustment unit 15 may be enabled when the coarse lock signal CO_LOCK is activated, and may be disabled when the fine lock signal FI_LOCK is activated. That is, the size adjustment unit 15 may be enabled when a difference between the phases of the first clock CLK1 and the second clock CLK2 is detected as being the coarse phase difference or less, and may be disabled when a difference between the phases of the first clock CLK1 and the second clock CLK2 is detected as being the fine phase difference or less.

More specifically, the size adjustment unit 15 may adjust the amount of the control current in order to maintain the level of the control voltage CONV within a range between the set first level and the set second level during the enable interval of the size adjustment unit 15. Further, after adjusting the amount of the control current during the enable interval of the size adjustment unit 15, the size adjustment unit 15 may maintain the amount of the control current that has been adjusted during the enable interval without any change although the size adjustment unit 15 is disabled. That is, after adjusting the amount of the control current during the enable interval, the size adjustment unit 15 may maintain the amount of the control current that has been adjusted during the enable interval without any change until the size adjustment unit 15 is reset in response to a reset signal RST.

According to an embodiment, the size adjustment unit 15 may set the amount of the control current to vary in the down fluctuation in response to the level of the control voltage CONV being placed in the interval in which the level of the control voltage CONV is higher than the first level for the first time during the enable interval of the size adjustment unit 15, and may maintain the state in which the size adjustment unit 15 has been set to change the amount of the control current in the down fluctuation even after the size adjustment unit 15 is disabled. That is, the size adjustment unit 15 may maintain the state in which the size adjustment unit 15 has been set to change the amount of the control current in the down fluctuation until the size adjustment unit 15 is reset in response to the reset signal RST.

According to another embodiment, the size adjustment unit 15 may set the amount of the control current to vary in the up fluctuation in response to the level of the control voltage CONV being placed in the interval in which the level of the control voltage CONV is less than the second level for the first time during the enable interval, and may maintain the state in which the size adjustment unit 15 has been set to change the amount of the control current in the up fluctuation even after the size adjustment unit 15 is disabled. That is, the size adjustment unit 15 may maintain the state in which the size adjustment unit 15 has been set to change the amount of the control current in the up fluctuation until the size adjustment unit 15 is reset in response to the reset signal RST.

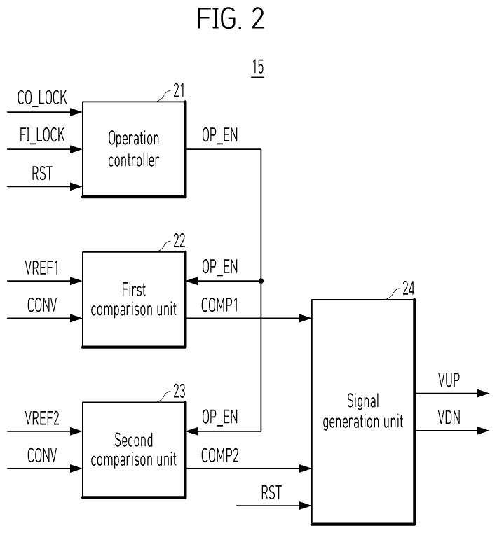

FIG. 2 is a block diagram illustrating a detailed configuration of the size adjustment unit 15 illustrated in FIG. 1, according to an embodiment of the present disclosure.

Referring to FIG. 2, the size adjustment unit 15, among the components of the phase-locked loop according to an embodiment of the present disclosure, which is illustrated in FIG. 1, may include an operation controller 21, a first comparison unit (i.e., a first comparison circuit) 22, a second comparison unit (i.e., a second comparison circuit) 23, and a signal generation unit (i.e., a signal generation circuit) 24.

In this case, the operation controller 21 may generate an operation enable signal OP_EN that is activated in response to the coarse lock signal CO_LOCK being activated and that is deactivated in response to the fine lock signal FI_LOCK being activated. That is, the operation controller 21 may activate the operation enable signal OP_EN when the lock detection unit 16 detects that a difference between the phases of the first clock CLK1 and the second clock CLK2 is the coarse phase difference or less. Furthermore, the operation controller 21 may deactivate the operation enable signal OP_EN at a time at which the lock detection unit 16 detects that a difference between the phases of the first clock CLK1 and the second clock CLK2 is the fine phase difference or less.

Further, the operation controller 21 may reset the state of the operation enable signal OP_EN as the deactivation state in response to the reset signal RST.

Further, the first comparison unit 22 may generate a first comparison signal COMP1 by comparing the level of the control voltage CONV with the first reference voltage VREF1 set as the first level during the interval in which the operation enable signal OP_EN generated by the operation controller 21 is activated. For example, the first comparison unit 22 may activate the first comparison signal COMP1 during the interval in which the level of the control voltage CONV is higher than the first level during the interval in which the operation enable signal OP_EN has been activated. In contrast, the first comparison unit 22 may deactivate the first comparison signal COMP1 during the interval in which the level of the control voltage CONV is the first level or less during the interval in which the operation enable signal OP_EN has been activated.

Further, the second comparison unit 23 may generate a second comparison signal COMP2 by comparing the level of the control voltage CONV with the second reference voltage VREF2 set as the second level during the interval in which the operation enable signal OP_EN generated by the operation controller 21 has been activated. For example, the second comparison unit 23 may activate the second comparison signal COMP2 during the interval in which the level of the control voltage CONV is less than the second level during the interval in which the operation enable signal OP_EN has been activated. In contrast, the second comparison unit 23 may deactivate the second comparison signal COMP2 during the interval in which the level of the control voltage CONV is the second level or more during the interval in which the operation enable signal OP_EN has been activated.

Further, the signal generation unit 24 may control whether to activate the down signal VDN in response to the first comparison signal COMP1, and may control whether to activate the up signal VUP in response to the second comparison signal COMP2.

Further, the signal generation unit 24 may reset the state of the up signal VUP and the down signal VDN to the deactivation state in response to the reset signal RST.

In other words, when the level of the control voltage CONV is higher than the first level, the first comparison signal COMP1 may be activated by the first comparison unit 22, and the second comparison signal COMP2 may be deactivated by the second comparison unit 23. In such a case, the down signal VDN may be activated and the up signal VUP may be deactivated, by the signal generation unit 24.

Further, when the level of the control voltage CONV is the first level or less and the second level or more, the first comparison signal COMP1 may be deactivated by the first comparison unit 22, and the second comparison signal COMP2 may be deactivated by the second comparison unit 23. In such a case, the down signal VDN may be deactivated and the up signal VUP may also be deactivated, by the signal generation unit 24.

Furthermore, when the level of the control voltage CONV is less than the second level, the first comparison signal COMP1 may be deactivated by the first comparison unit 22, and the second comparison signal COMP2 may be activated by the second comparison unit 23. In such a case, the up signal VUP may be activated and the down signal VDN may be deactivated, by the signal generation unit 24.

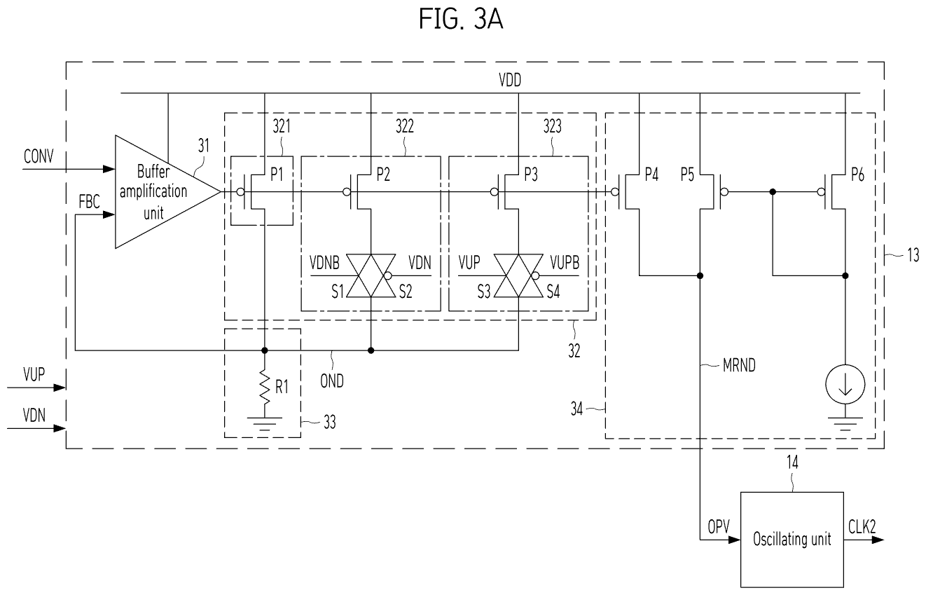

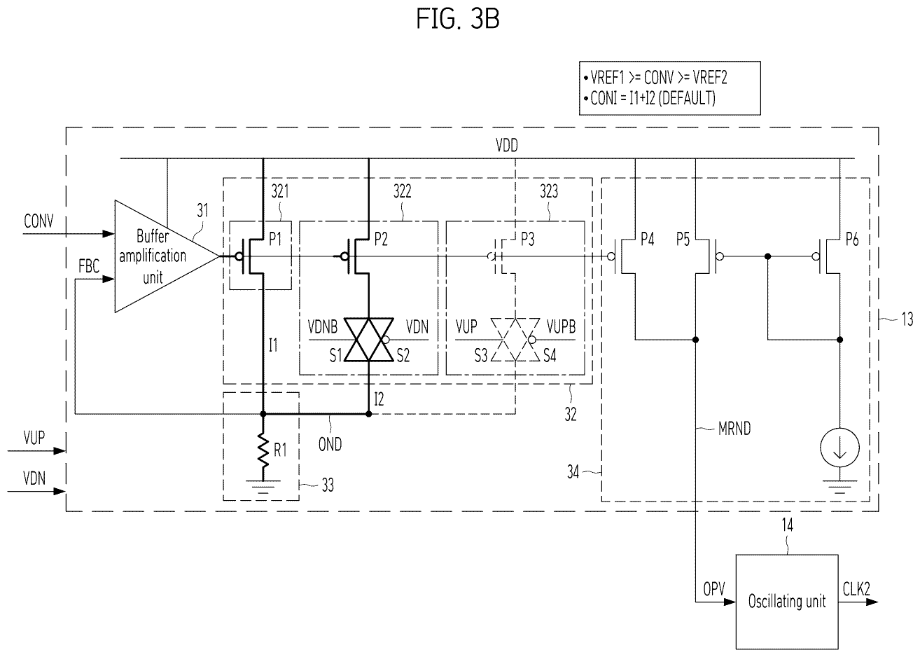

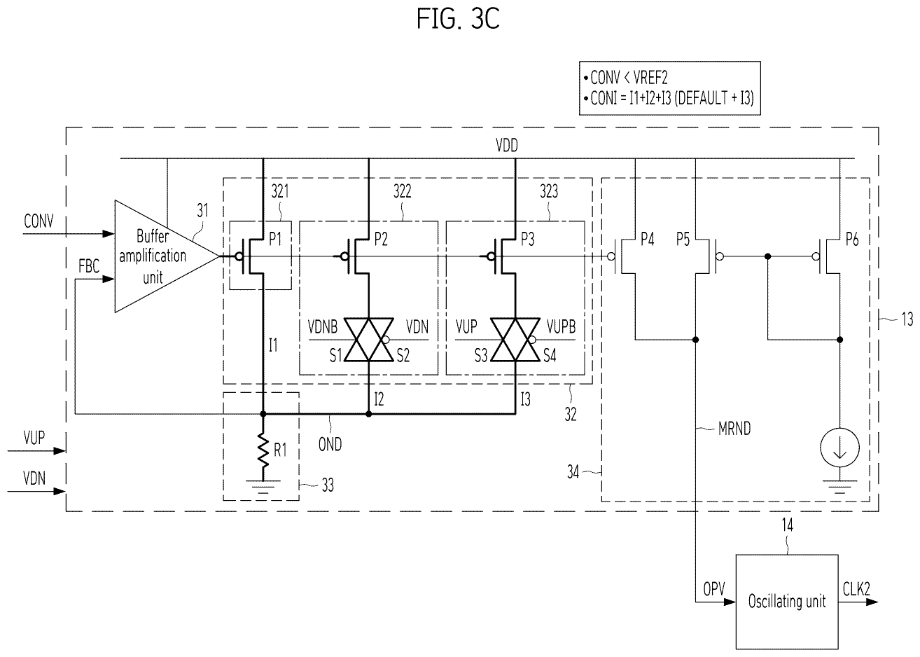

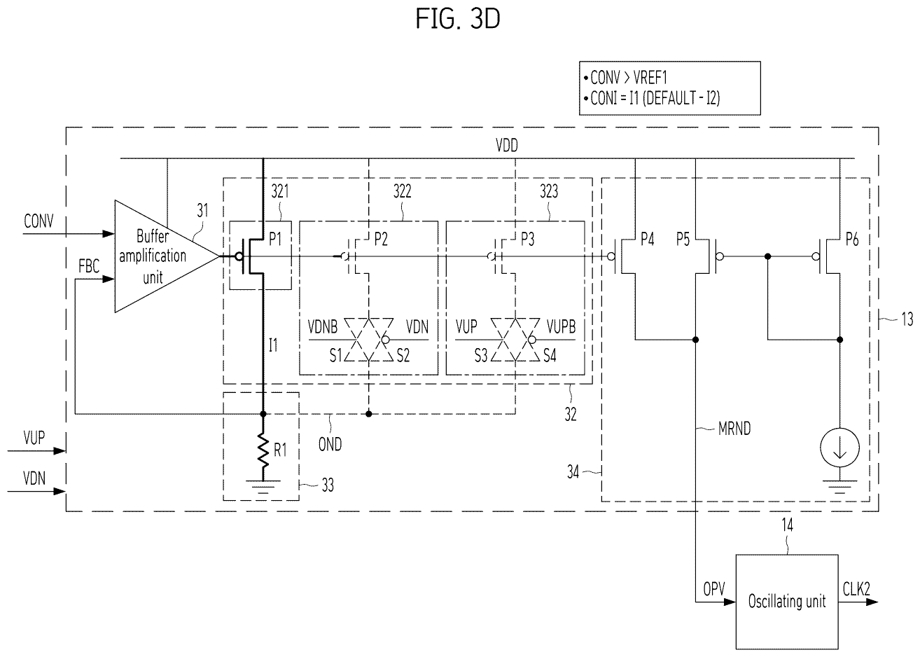

FIGS. 3A to 3D are circuit diagrams for describing a detailed configuration and an operation of the voltage generation unit 13 illustrated in FIG. 1, according to an embodiment of the present disclosure.

First, referring to FIG. 3A, the voltage generation unit 13, among the components of the phase-locked loop according to an embodiment of the present disclosure, which is illustrated in FIG. 1, may include a buffer amplification unit (i.e., a buffer amplification circuit) 31, a current adjustment unit (i.e., a current adjustment circuit) 32, a distribution unit (i.e., a distribution circuit) 33, and an operation voltage generation unit (i.e., an operation voltage generation circuit) 34. Furthermore, the current adjustment unit 32 may include a first adjustment unit (i.e., a first adjustment circuit) 321, a second adjustment unit (i.e., a second adjustment circuit) 322, and a third adjustment unit (i.e., a third adjustment circuit) 323.

In this instance, the buffer amplification unit 31 may adjust the level of an output voltage in response to a difference between the levels of the control voltage CONV and a feedback voltage FBC.

For example, when the level of the control voltage CONV is higher than the level of the feedback voltage FBC, the buffer amplification unit 31 may lower the level of the output voltage in the direction of the level of a ground voltage. In this instance, the buffer amplification unit 31 may adjust the amount of the level of the output voltage that drops in the direction of the level of the ground voltage depending on how greater is a difference between the level of the control voltage CONV and the level of the feedback voltage FBC.

Further, the buffer amplification unit 31 may raise the level of the output voltage in the direction of the level of a source voltage VDD when the level of the control voltage CONV is lower than the level of the feedback voltage FBC. In this instance, the buffer amplification unit 31 may adjust the amount of the level of the output voltage that rises in the direction of the level of the source voltage VDD depending on how less is a difference between the level of the control voltage CONV and the level of the feedback voltage FBC.

Further, the current adjustment unit 32 may adjust the amount of the control current CONI that is supplied to an output node OND of the buffer amplification unit 31 in response to the output voltage of the buffer amplification unit 31, the down signal VDN, and the up signal VUP.

In this instance, the first adjustment unit 321 included in the current adjustment unit 32 may adjust the amount of a first current I1 that flows from a terminal for the source voltage VDD to the output node OND of the buffer amplification unit 31 in response to the output voltage of the buffer amplification unit 31.

More specifically, the first adjustment unit 321 may include a P-channel MOSFET (PMOS) transistor P1 having a gate stage to which the output voltage of the buffer amplification unit 31 is input, a source stage to which the terminal for the source voltage VDD is connected, and a drain stage to which the output node OND of the buffer amplification unit 31 is connected.

Further, the second adjustment unit 322 included in the current adjustment unit 32 may adjust the amount of a second current I2 that flows from the terminal for the source voltage VDD to the output node OND of the buffer amplification unit 31 in response to the output voltage of the buffer amplification unit 31 and the down signal VDN.

More specifically, the second adjustment unit 322 may include a switch S1, S2 having a positive input stage to which an inverted signal VDNB of the down signal VDN is input and a negative input stage to which the down signal VDN is input. The switch S1, S2 may control the on/off of a connection between a transfer node of the switch S1, S2 and the output node OND of the buffer amplification unit 31, and a PMOS transistor P2 having a gate stage to which the output voltage of the buffer amplification unit 31 is input, a source stage to which the terminal for the source voltage VDD is connected, and a drain stage to which the transfer node of the switch S1, S2 is connected. In this instance, the switch S1, S2 may turn on the connection between the transfer node of the switch S1, S2 and the output node OND of the buffer amplification unit 31 during the interval in which the down signal VDN has been deactivated and turn off the connection between the transfer node of the switch S1, S2 and the output node OND of the buffer amplification unit 31 during the interval in which the down signal VDN has been activated because the inverted signal VDNB of the down signal VDN is input to the positive input stage of the switch S1, S2 and the down signal VDN is input to the negative input stage of the switch S1, S2. That is, the second adjustment unit 322 may be enabled during the interval in which the down signal VDN has been deactivated and may supply the second current I2 from the terminal for the source voltage VDD to the output node OND of the buffer amplification unit 31. The second adjustment unit 322 may be disabled during the interval in which the down signal VDN has been activated, and might not supply the second current I2 from the terminal for the source voltage VDD to the output node OND of the buffer amplification unit 31.

Further, the third adjustment unit 323 included in the current adjustment unit 32 may adjust the amount of a third current I3 that flows from the terminal for the source voltage VDD to the output node OND of the buffer amplification unit 31 in response to the output voltage of the buffer amplification unit 31 and the up signal VUP.

More specifically, the third adjustment unit 323 may include a switch S3, S4 having a positive input stage to which the up signal VUP is input, a negative input stage to which an inverted signal VUPB of the up signal VUP is input. The switch S3, S4 may control the on/off of a connection between a transfer node of the switch S3, S4 and the output node OND of the buffer amplification unit 31, and a PMOS transistor P3 having a gate stage to which the output voltage of the buffer amplification unit 31 is input, a source stage to which the terminal for the source voltage VDD is connected, and a drain stage to which the transfer node of the switch S3, S4 is connected. In this instance, the switch S3, S4 may turn on the connection between the transfer node of the switch S3, S4 and the output node OND of the buffer amplification unit 31 during the interval in which the up signal VUP has been activated and turn off the connection between the transfer node of the switch S3, S4 and the output node OND of the buffer amplification unit 31 during the interval in which the up signal VUP has been deactivated because the up signal VUP is input to the positive input stage the switch S3, S4 and the inverted signal VUPB of the up signal VUP is input to the negative input stage of the switch S3, S4. That is, the third adjustment unit 323 may be enabled during the interval in which the up signal VUP has been activated and may supply the third current I3 from the terminal for the source voltage VDD to the output node OND of the buffer amplification unit 31. The third adjustment unit 323 may be disabled during the interval in which the up signal VUP has been deactivated, and might not supply the third current I3 from the terminal for the source voltage VDD to the output node OND of the buffer amplification unit 31.

In other words, the first to third adjustment units 321, 322, and 323 included in the current adjustment unit 32 may adjust the amount of the current that flows from the terminal for the source voltage VDD to the output node OND of the buffer amplification unit 31 in response to the current adjustment signal VUP, VDN that is output from the size adjustment unit 15, that is, the up signal VUP and the down signal VDN that are output from the signal generation unit 24 included in the size adjustment unit 15.

According to an embodiment, when both the up signal VUP and the down signal VDN are deactivated in the signal generation unit 24, the first current I1 and the second current I2 may be supplied from the terminal for the source voltage VDD to the output node OND of the buffer amplification unit 31 through the first adjustment unit 321 and the second adjustment unit 322.

According to another embodiment, when the up signal VUP is deactivated and the down signal VDN is activated in the signal generation unit 24, the first current I1 may be supplied from the terminal for the source voltage VDD to the output node OND of the buffer amplification unit 31 through the first adjustment unit 321.

According to still another embodiment, when the up signal VUP is activated and the down signal VDN is deactivated in the signal generation unit 24, the first to third currents I1, I2, and I3 may be supplied from the terminal for the source voltage VDD to the output node OND of the buffer amplification unit 31 through the first to third adjustment units 321, 322, and 323.

Furthermore, the distribution unit 33 may generate the feedback voltage FBC by distributing a voltage loaded onto the output node OND of the buffer amplification unit 31.

More specifically, the distribution unit 33 may include a resistor R1 between the output node OND of the buffer amplification unit 31 and the stage of the ground voltage. Accordingly, the distribution unit 33 may generate the feedback voltage FBC by distributing a voltage loaded onto the output node OND according to the size of the resistor R1.

Further, the operation voltage generation unit 34 may generate the operating voltage OPV by being connected to the output node OND of the buffer amplification unit 31 in a current mirror form.

More specifically, the operation voltage generation unit 34 may include a PMOS transistor P4 having a gate stage to which the output voltage of the buffer amplification unit 31 is input, a source stage connected to the terminal for the source voltage VDD, and a drain stage connected to a mirroring node MRND, and two PMOS transistors P5 and P6 that are connected between the terminal for the source voltage VDD and the mirroring node MRND in a cascode form. The operation voltage generation unit 34 can mirror a current that flows from the terminal for the source voltage VDD to the output node OND of the buffer amplification unit 31 and supply the current from the terminal for the source voltage VDD to the mirroring node MRND because the output voltage of the buffer amplification unit 31 is input to the gate of the PMOS transistor P4 and the two PMOS transistors P5 and P6 are connected in the cascode form as described above.

Referring to FIGS. 1, 2, and 3B, when the level of the control voltage CONV is the first level or less and the second level or more (VREF1≥CONV≥VREF2), the first comparison signal COMP1 may be deactivated by the first comparison unit 22 included in the size adjustment unit 15, and the second comparison signal COMP2 may be deactivated by the second comparison unit 23 included in the size adjustment unit 15.

Furthermore, the down signal VDN may be deactivated and the up signal VUP may also be deactivated, by the signal generation unit 24 included in the size adjustment unit 15.

Accordingly, the voltage generation unit 13 may control the sum current of the first current I1 and the second current I2 to flow between the terminal for the source voltage VDD and the output node OND of the buffer amplification unit 31 as the control current CONI, by enabling the first adjustment unit 321 and the second adjustment unit 322 included in the current adjustment unit 32 and disabling the third adjustment unit 323.

In accordance with an embodiment of the present disclosure, in instances in which the sum current of the first current I1 and the second current I2 flows between the terminal for the source voltage VDD and the output node OND of the buffer amplification unit 31 as the control current CONI as described above, the amount of the control current CONI may vary in the default fluctuation DEFAULT. Furthermore, if the amount of the control current CONI is assumed to vary in the default fluctuation DEFAULT, the level of the operating voltage OPV may vary in the default interval in accordance with a change in the level of the control voltage CONV in the state in which the level of the control voltage CONV is the first level or less and the second level or more (VREF1≥CONV≥VREF2).

Referring to FIGS. 1, 2, 3B, and 3C, when the level of the control voltage CONV is placed in the interval (CONV<VREF2) in which the level of the control voltage CONV is less than the second level, the first comparison signal COMP1 may be deactivated by the first comparison unit 22 included in the size adjustment unit 15, and the second comparison signal COMP2 may be activated by the second comparison unit 23 included in the size adjustment unit 15. Furthermore, the down signal VDN may be deactivated and the up signal VUP may be activated, by the signal generation unit 24 included in the size adjustment unit 15.

Accordingly, the voltage generation unit 13 may control the sum current of the first current I1, the second current I2, and the third current I3 to flow between the terminal for the source voltage VDD and the output node OND of the buffer amplification unit 31 as the control current CONI by enabling all of the first adjustment unit 321, the second adjustment unit 322, and the third adjustment unit 323 included in the current adjustment unit 32.

The case in which the sum current of the first current I1, the second current I2, and the third current I3 flows between the terminal for the source voltage VDD and the output node OND of the buffer amplification unit 31 as the control current CONI as described above may be said to be a case in which the amount of the control current CONI varies in the up fluctuation (DEFAULT+I3) relatively greater than the default fluctuation DEFAULT. When the amount of the control current CONI varies in the up fluctuation (DEFAULT+I3) greater than the default fluctuation DEFAULT as described above, the level of the operating voltage OPV may be changed in the default interval in accordance with a change in the level of the operating voltage OPV in the state (CONV<VREF2) in which the control voltage CONV is less than the second level.

In other words, the size adjustment unit 15 may change the level of the operating voltage OPV in the default interval by controlling the amount of the control current CONI to vary in the up fluctuation (DEFAULT+I3) within the voltage generation unit 13 although the control voltage CONV is in the state in which the level of the control voltage CONV is placed in the interval (CONV<VREF2) in which the level of the control voltage CONV is less than the second level. If the level of the operating voltage OPV varies in the default interval during the interval (CONV<VREF2) in which the level of the control voltage CONV is less than the second level due to an operation of the size adjustment unit 15 as described above, as a phase-locked loop operation through the oscillating unit 14, the phase detection unit 11, the charge pumping unit 12, and the voltage generation unit 13 is repeated, the level of the control voltage CONV, which is placed in the interval (CONV<VREF2) in which the level of the control voltage CONV is less than the second level, may rise to the second level or more.

Referring to FIGS. 1, 2, 3B, and 3D, if the level of the control voltage CONV is placed in the interval (CONV>VREF1) in which the level of the control voltage CONV is higher than the first level, the first comparison signal COMP1 may be activated by the first comparison unit 22 included in the size adjustment unit 15, and the second comparison signal COMP2 may be deactivated by the second comparison unit 23 included in the size adjustment unit 15. Furthermore, the down signal VDN may be activated and the up signal VUP may be deactivated, by the signal generation unit 24 included in the size adjustment unit 15.

Accordingly, the voltage generation unit 13 may control the first current I1 to flow between the terminal for the source voltage VDD and the output node OND of the buffer amplification unit 31 as the control current CONI by enabling only the first adjustment unit 321 included in the current adjustment unit 32 and disabling both the second adjustment unit 322 and the third adjustment unit 323.

The case in which the first current I1 flows between the terminal for the source voltage VDD and the output node OND of the buffer amplification unit 31 as the control current CONI as described above may be said to be a case in which the amount of the control current CONI varies in the down fluctuation (DEFAULT−I2) is relatively smaller than the default fluctuation DEFAULT. If the amount of the control current CONI varies in the down fluctuation (DEFAULT−I2) is smaller than the default fluctuation DEFAULT as described above, the level of the operating voltage OPV may be changed in the default interval in accordance with a change in the level of the control voltage CONV in the state in which (CONV>VREF1) the level of the control voltage CONV is higher than the first level.

In other words, the size adjustment unit 15 may change the level of the operating voltage OPV in the default interval by controlling the amount of the control current CONI to vary in the down fluctuation (DEFAULT−I2) within the voltage generation unit 13 although the control voltage CONV is in the state in which the level of the control voltage CONV has been placed in the interval (CONV>VREF1) in which the level of the control voltage CONV is higher than the first level. If the level of the operating voltage OPV varies in the default interval during the interval (CONV>VREF1) in which the level of the control voltage CONV is higher than the first level due to an operation of the size adjustment unit 15 as described above, as a phase-locked loop operation through the oscillating unit 14, the phase detection unit 11, the charge pumping unit 12, and the voltage generation unit 13 is repeated, the level of the control voltage CONV, which has been placed in the interval (CONV>VREF1) in which the level of the control voltage CONV is higher than the first level, may drop to the first level or less.

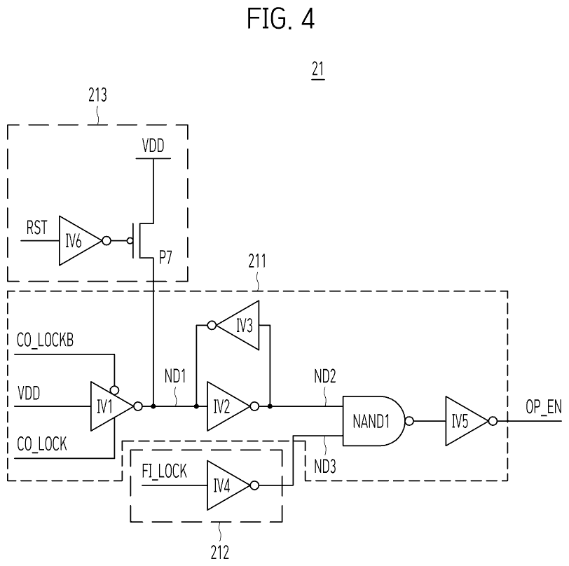

FIG. 4 is a circuit diagram illustrating a detailed configuration of the operation controller 21 illustrated in FIG. 2, according to an embodiment of the present disclosure.

Referring to FIG. 4, a detailed circuit construction of the operation controller 21, which is illustrated in FIG. 2 and included in the size adjustment unit 15 (illustrated among the components of the phase-locked loop of FIG. 1), may be seen.

First, as described with reference to FIG. 2, the operation controller 21 may generate the operation enable signal OP_EN that is activated in response to the coarse lock signal CO_LOCK being activated and that is deactivated in response to the fine lock signal FI_LOCK being activated.

Specifically, the operation controller 21 may include a first activation controller 211, a deactivation controller 212, and a first reset unit 213.

In this case, the first activation controller 211 may activate the operation enable signal OP_EN in response to the coarse lock signal CO_LOCK being activated for the first time, and may then maintain the operation enable signal OP_EN in the activation state regardless of whether the coarse lock signal CO_LOCK has been activated.

The deactivation controller 212 may be configured to deactivate the operation enable signal OP_EN in response to the fine lock signal FI_LOCK being activated.

The first reset unit 213 may be configured to reset the state of the operation enable signal OP_EN to the deactivation state in response to the reset signal RST.

More specifically, the first activation controller 211 may include a first inverter IV1 that drives the ground voltage to a first node ND1 in response to the coarse lock signal CO_LOCK input to a positive input stage of the first inverter IV1 and an inverted signal CO_LOCKB of the coarse lock signal CO_LOCK, which is input to a negative input stage of the first inverter IV1, second and third inverters IV2 and IV3 connected between the first node ND1 and a second node ND2 in a latch form, and a first NAND gate NAND1 and a fifth inverter IV5 that generate the operation enable signal OP_EN by performing an AND operation on the logic value of the second node ND2 and the logic value of the third node ND3.

Furthermore, the deactivation controller 212 may include a fourth inverter IV4 that drives a third node ND3 by inverting the fine lock signal FI_LOCK.

In other words, the first activation controller 211 may drive the ground voltage to the first node ND1 in response to the coarse lock signal CO_LOCK being activated, that is, in response to the coarse lock signal CO_LOCK transitioning to the level of the source voltage VDD, that is, a logic high level, and the inverted signal CO_LOCKB of the coarse lock signal CO_LOCK transitioning to the level of the ground voltage, that is, a logic low level. Furthermore, the first activation controller 211 may drive the second node ND2 to the source voltage VDD by latching the ground voltage that has been driven in the first node ND1. At this time, the ground voltage of the first node ND1 and the source voltage VDD of the second node ND2 are in the state in which the ground voltage and the source voltage VDD have been latched by the second and third inverters IV2 and IV3. Although the coarse lock signal CO_LOCK is deactivated after the ground voltage is driven to the first node ND1, that is, although the coarse lock signal CO_LOCK transitions to the level of the ground voltage, that is, a logic low level, and the inverted signal CO_LOCKB of the coarse lock signal CO_LOCK transitions to the level of the source voltage VDD, that is, a logic high level, the ground voltage of the first node ND1 and the source voltage VDD of the second node ND2 may maintain their levels without being floated.

Furthermore, the deactivation controller 212 may drive the third node ND3 to the level of the source voltage VDD, that is, a logic high level, when the fine lock signal FI_LOCK is in the deactivation state, that is, in the state in which the level of the fine lock signal FI_LOCK is the level of the ground voltage, that is, a logic low level. Furthermore, the deactivation controller 212 may drive the third node ND3 to the level of the ground voltage, that is, a logic low level, when the fine lock signal FI_LOCK is the activation state, that is, in the state in which the level of the fine lock signal FI_LOCK is the level of the source voltage VDD, that is, a logic high level.

After the coarse lock signal CO_LOCK is activated by an operating characteristic of the lock detection unit 16, the fine lock signal FI_LOCK may be activated (but the opposite is impossible (or barred)). Accordingly, the fine lock signal FI_LOCK may be in the deactivation state at a timing at which the coarse lock signal CO_LOCK is activated. That is, at the timing at which the first activation controller 211 drives the second node ND2 to the level of the source voltage VDD corresponding to a logic high level in response to the coarse lock signal CO_LOCK, the third node ND3 may be in the state in which the third node ND3 has the level of the source voltage VDD corresponding to a logic high level.

Accordingly, the first activation controller 211 may drive the operation enable signal OP_EN to the level of the source voltage VDD corresponding to a logic high level by driving the second node ND2 to the level of the source voltage VDD corresponding to a logic high level in response to the coarse lock signal CO_LOCK being activated for the first time.

Next, the deactivation controller 212 may drive the operation enable signal OP_EN to the level of the ground voltage corresponding to a logic low level by driving the third node ND3 to the level of the ground voltage corresponding to a logic low level in response to the fine lock signal FI_LOCK being activated.

Accordingly, by the operations of the first activation controller 211 and the deactivation controller 212, the operation enable signal OP_EN may be activated to a logic high level in response to the coarse lock signal CO_LOCK being activated to a logic high level, and the operation enable signal OP_EN may be deactivated to a logic low level in response to the fine lock signal FI_LOCK being activated to a logic high level. Furthermore, the operation enable signal OP_EN may continuously maintain the activation state in the logic high level until the operation enable signal OP_EN is activated in response to the coarse lock signal CO_LOCK being activated to a logic high level and then deactivated in response to the fine lock signal FI_LOCK being activated to a logic high level because a latch is included in the first activation controller 211.

Furthermore, the first reset unit 213 may include a PMOS transistor P7 that supplies the source voltage VDD supplied to a source stage of the PMOS transistor P7 to the first node ND1 connected to a drain stage of the PMOS transistor P7, in response to the reset signal RST that is input to a gate stage of the PMOS transistor P7. That is, the first reset unit 213 may supply the source voltage VDD to the first node ND1 in response to the reset signal RST transitioning to the level of the source voltage VDD, that is, a logic high level. That is, the first reset unit 213 may reset the operation enable signal OP_EN to the level of the ground voltage, that is, a logic low level. For example, the reset signal RST may be a power down mode entry signal.

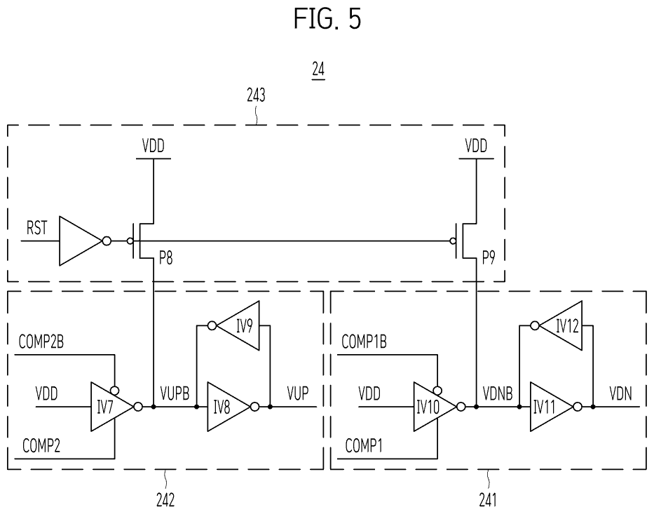

FIG. 5 is a circuit diagram illustrating a detailed configuration of the signal generation unit 24 illustrated in FIG. 2, according to an embodiment of the present disclosure.

Referring to FIG. 5, a detailed circuit construction of the signal generation unit 24 that is illustrated in FIG. 2 and that is included in the size adjustment unit 15 according to an embodiment of the present disclosure may be seen.

First, as described with reference to FIG. 2, the signal generation unit 24 may control whether to activate the down signal VDN in response to the first comparison signal COMP1, and may control whether to activate the up signal VUP in response to the second comparison signal COMP2.

Specifically, the signal generation unit 24 may include a second activation controller 241, a third activation controller 242, and a second reset unit 243.

In this case, the second activation controller 241 may activate the down signal VDN in response to the first comparison signal COMP1 that is output by the first comparison unit 22 being activated for the first time based on the level of the control voltage CONV, which is higher than the first level, and may then maintain the down signal VDN in the activation state regardless of whether the first comparison signal COMP1 has been activated.

Furthermore, the third activation controller 242 may activate the up signal VUP in response to the second comparison signal COMP2 that is output by the second comparison unit 23 being activated for the first time based on the level of the control voltage CONV, which is less than the second level, and may then maintain the up signal VUP in the activation state regardless of whether the second comparison signal COMP2 has been activated.

Furthermore, the second reset unit 243 may reset the state of each of the up signal VUP and the down signal VDN to the deactivation state in response to the reset signal RST.

More specifically, the second activation controller 241 may include tenth and eleventh inverters IV10 and IV11 that activates the down signal VDN to the level of the source voltage VDD, that is, a logic high level, in response to the first comparison signal COMP1 that is input to a positive input stage of the tenth inverter IV10 and an inverted signal COMP1B of the first comparison signal COMP1, which is input to a negative input stage of the first comparison signal COMP1, and a twelfth inverter IV12 that is connected to the eleventh inverter IV11 in a latch form.

That is, the second activation controller 241 may change the level of an inverted signal VDNB of the down signal VDN into the level of the ground voltage, in response to the first comparison signal COMP1 being activated, that is, the first comparison signal COMP1 transitioning to the level of the source voltage VDD, that is, a logic high level, and the inverted signal COMP1B of the first comparison signal COMP1 transitioning to the level of the ground voltage, that is, a logic low level. Furthermore, the second activation controller 241 may change the level of the down signal VDN into the level of the source voltage VDD in the activation state by latching the ground voltage of a node onto which the inverted signal VDNB of the down signal VDN has been loaded. At this time, the ground voltage of the node onto which the inverted signal VDNB of the down signal VDN has been loaded and the source voltage VDD of a node onto which the down signal VDN has been loaded are in the state in which the ground voltage and the source voltage VDD have been latched by the eleventh and twelfth inverters IV11 and IV12. Accordingly, although the first comparison signal COMP1 is activated for the first time and then deactivated, that is, although the first comparison signal COMP1 transitions to the level of the ground voltage, that is, a logic low level, and the inverted signal COMP1B of the first comparison signal COMP1 transitions to the level of the source voltage VDD, that is, a logic high level, the ground voltage of the node onto which the inverted signal VDNB of the down signal VDN has been loaded and the source voltage VDD of the node onto which the down signal VDN has been loaded may maintain their levels without being floated.

Furthermore, the third activation controller 242 may include seventh and eighth inverters IV7 and IV8 that activate the down signal VDN to the level of the source voltage VDD, that is, a logic high level, in response to the second comparison signal COMP2 that is input to a positive input stage of the seventh inverter IV7 and an inverted signal COMP2B of the second comparison signal COMP2, which is input to a negative input stage of the seventh inverter IV7, and a ninth inverter IV9 that is connected to the eighth inverter IV8 in a latch form.

That is, the third activation controller 242 may change the level of the inverted signal VUPB of the up signal VUP to the level of the ground voltage in response to the second comparison signal COMP2 being activated, that is, the second comparison signal COMP2 transitioning to the level of the source voltage VDD, that is, a logic high level, and the inverted signal COMP2B of the second comparison signal COMP2 transitioning to the level of the ground voltage, that is, a logic low level. Furthermore, the third activation controller 242 may change the level of the up signal VUP into the source voltage VDD in the activation state by latching the ground voltage of a node onto which the inverted signal VUPB of the up signal VUP has been loaded. At this time, the ground voltage of the node onto which the inverted signal VUPB of the up signal VUP has been loaded and the source voltage VDD of a node onto which the up signal VUP has been loaded are in the state in which the ground voltage and the source voltage VDD have been latched by the eighth and ninth inverters IV8 and IV9. Accordingly, although the second comparison signal COMP2 is activated for the first time and then deactivated, that is, although the second comparison signal COMP2 transitions to the level of the ground voltage, that is, a logic low level, and the inverted signal COMP2B of the second comparison signal COMP2 transitions to the level of the source voltage VDD, that is, a logic high level, the ground voltage of the node onto which the inverted signal VUPB of the up signal VUP has been loaded and the source voltage VDD of the node onto which the up signal VUP has been loaded may maintain their levels without being floated.

Furthermore, the second reset unit 243 may include a PMOS transistor P9 that supplies the source voltage VDD supplied to a source stage of the PMOS transistor P9 to the node that is connected to a drain stage of the PMOS transistor P9 and onto which the inverted signal VDNB of the down signal VDN has been loaded, in response to the reset signal RST that is input to a gate stage of the PMOS transistor P9, and a PMOS transistor P8 that supplies the source voltage VDD supplied to a source stage of the PMOS transistor P8 to the node that is connected to a drain stage of the PMOS transistor P8 and onto which the inverted signal VUPB of the up signal VUP has been loaded, in response to the reset signal RST that is input to a gate stage of the PMOS transistor P8. That is, the second reset unit 243 may supply the source voltage VDD to each of the nodes onto which the inverted signal VDNB of the down signal VDN has been loaded and the node onto which the inverted signal VUPB of the up signal VUP has been loaded, in response to the reset signal RST transitioning to the level of the source voltage VDD, that is, a logic high level. That is, the second reset unit 243 may reset each of the up signal VUP and the down signal VDN to the level of the ground voltage, that is, a logic low level. For example, the reset signal RST may be a power down mode entry signal.

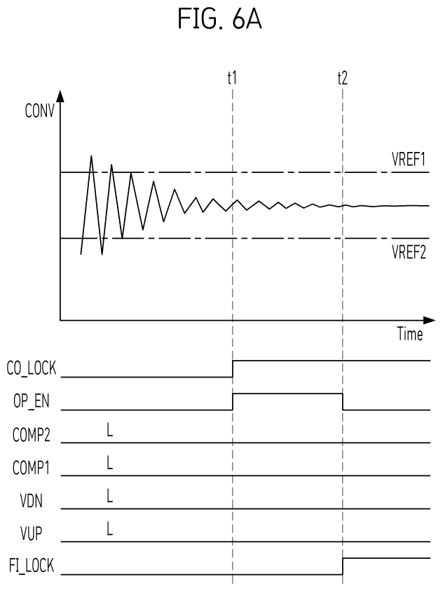

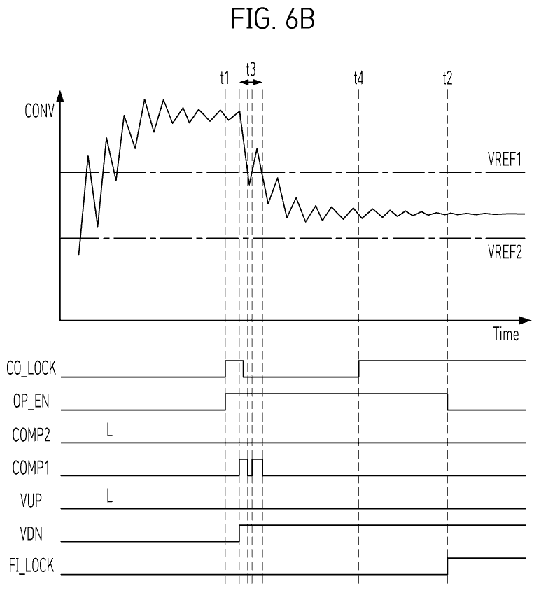

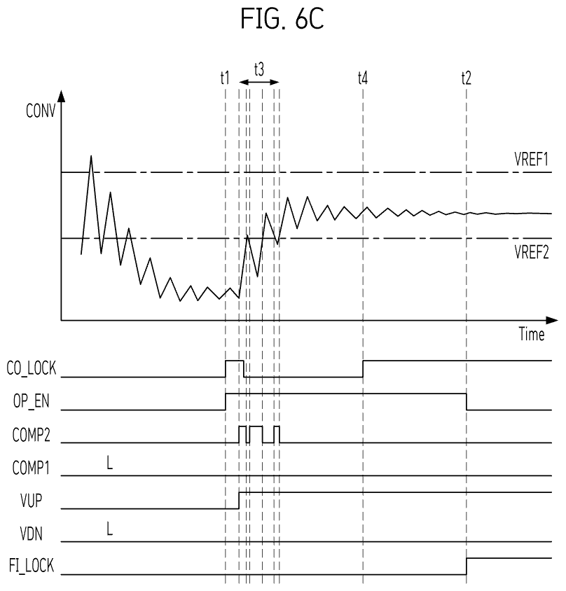

FIGS. 6A to 6C are waveform diagrams for describing an operation of the phase-locked loop, according to an embodiment of the present disclosure.

First, referring to FIG. 6A, an operation of the size adjustment unit 15 when the control voltage CONV is continuously maintained in the state (VREF1≥CONV≥VREF2) in which the level of the control voltage CONV is the first level or less and the second level or more after the coarse lock signal CO_LOCK is activated may be seen.

Specifically, at a timing at which an operation of the phase-locked loop is started, the first clock CLK1 and the second clock CLK2 may be in the state in which a difference between the phases of the first clock CLK1 and the second clock CLK2 is great. In such a state, as the phase detection unit 11, the charge pumping unit 12, the voltage generation unit 13, and the oscillating unit 14 repeatedly operate, the rise and fall of the level of the control voltage CONV may be greatly repeated.

The lock detection unit 16 may maintain both the coarse lock signal CO_LOCK and the fine lock signal FI_LOCK in the deactivation state because the difference between the control voltage CONV is in the state in which the difference between the phases of the first clock CLK1 and the second clock CLK2 is greater than the coarse phase difference during the interval in which the rise and fall of the level of the control voltage CONV are greatly repeated as described above.

Thereafter, as the operation of the phase-locked loop proceeds, the control voltage CONV may be in the state (VREF1≥CONV≥VREF2) in which the level of the control voltage CONV is the first level or less and the second level or more as the difference between the phases of the first clock CLK1 and the second clock CLK2 is slowly narrowed. Next, at timing t1, the coarse lock signal CO_LOCK may be activated as the difference between the phases of the first clock CLK1 and the second clock CLK2 becomes the coarse phase difference or less.

Even after timing t1 at which the coarse lock signal CO_LOCK has been activated, the difference between the phases of the first clock CLK1 and the second clock CLK2 may be gradually narrowed as the state (VREF1≥CONV≥VREF2) in which the level of the control voltage CONV is the first level or less and the second level or more is continuously maintained. Next, at timing t2, the fine lock signal FI_LOCK may be activated as the difference between the phases of the first clock CLK1 and the second clock CLK2 becomes the fine phase difference or less.

As described above, the size adjustment unit 15 performs only the operation of activating the operation enable signal OP_EN to a logic high level between timing t1 and timing t2 because the control voltage CONV continuously maintains the state (VREF1≥CONV≥VREF2) in which the level of the control voltage CONV is the first level or less and the second level or more between timing t1 and timing t2, and may maintain all of the first comparison signal COMP1, the second comparison signal COMP2, the up signal VUP, and the down signal VDN to a logic low level in the deactivation state.

Furthermore, referring to FIG. 6B, an operation of the size adjustment unit 15 when the control voltage CONV is in the state (CONV>VREF1) in which the level of the control voltage CONV is higher than the first level after the coarse lock signal CO_LOCK is activated may be seen.

Specifically, at a timing at which the operation of the phase-locked loop is started, the first clock CLK1 and the second clock CLK2 may be in the state in which a difference between the phases of the first clock CLK1 and the second clock CLK2 is great. In such a state, as the phase detection unit 11, the charge pumping unit 12, the voltage generation unit 13, and the oscillating unit 14 repeatedly operate, the rise and fall of the level of the control voltage CONV may be greatly repeated.

The lock detection unit 16 may maintain both the coarse lock signal CO_LOCK and the fine lock signal FI_LOCK in the deactivation state because the control voltage CONV is in the state in which the difference between the phases of the first clock CLK1 and the second clock CLK2 is greater than the coarse phase difference during the interval in which the rise and fall of the level of the control voltage CONV is greatly repeated as described above.

Thereafter, as the operation of the phase-locked loop proceeds, the difference between the phases of the first clock CLK1 and the second clock CLK2 is slowly narrowed, but the control voltage CONV may be in the state (CONV>VREF1) in which the level of the control voltage CONV is higher than the first level as the rise of the level of the control voltage CONV is greater than the fall of the level of the control voltage CONV. Next, at timing t1, the coarse lock signal CO_LOCK may be activated as the difference between the phases of the first clock CLK1 and the second clock CLK2 becomes the coarse phase difference or less.

At timing t1 at which the coarse lock signal CO_LOCK is activated, the size adjustment unit 15 may perform an operation of activating the operation enable signal OP_EN to a logic high level.

Furthermore, after timing t1, the control voltage CONV is in the state (CONV>VREF1) in which the level of the control voltage CONV is higher than the first level. Accordingly, the size adjustment unit 15 may activate the first comparison signal COMP1 to a logic high level for the first time and activate the down signal VDN to a logic high level for the first time, at the start timing of an interval t3 that is slightly later than timing t1 (note that t represents a time based condition, either an instant in time, as in timing t1, t2, or t4 or an interval, as t3).

Furthermore, as the down signal VDN is activated to a logic high level by the size adjustment unit 15, the level of the control voltage CONV may greatly fall, and the control voltage CONV may instantly become the state (VREF1≥CONV) in which the level of the control voltage CONV is the first level or less.

The size adjustment unit 15 may instantly deactivate the first comparison signal COMP1 to a logic low level during the interval t3 because the control voltage CONV becomes the state (VREF1≥CONV) in which the level of the control voltage CONV is the first level or less even for a moment.

Furthermore, as the control voltage CONV becomes the state (VREF1≥CONV) in which the level of the control voltage CONV is the first level or less even for a moment, the difference between the phases of the first clock CLK1 and the second clock CLK2 may be greater than the coarse phase difference again. The lock detection unit 16 may deactivate the coarse lock signal CO_LOCK to a logic low level again during the interval t3, and may then continuously maintain the coarse lock signal CO_LOCK in the deactivation state up to timing t4.

However, the size adjustment unit 15 can prevent the first comparison signal COMP1, which has been instantly deactivated to a logic low level during the interval t3, and the coarse lock signal CO_LOCK, which has been deactivated to a logic low level during the interval t3 and maintains the deactivation state up to timing t4, from affecting whether to activate the down signal VDN. That is, the size adjustment unit 15 may control the down signal VDN that has been activated for the first time at the start timing of the interval t3 to maintain the state in which the down signal VDN has been activated to a logic high level, separately from the operation of instantly deactivating the first comparison signal COMP1 to a logic low level during the interval t3 and the operation of the coarse lock signal CO_LOCK being deactivated to a logic low level during the interval t3 and maintaining the deactivation state up to timing t4.

As the down signal VDN continuously maintains the state in which the down signal VDN has been activated to a logic high level and the control voltage CONV maintains the state (VREF1≥CONV) in which the level of the control voltage CONV is the first level or less as described above, the difference between the phases of the first clock CLK1 and the second clock CLK2 may be gradually narrowed. Next, at timing t2, the fine lock signal FI_LOCK may be activated as the difference between the phases of the first clock CLK1 and the second clock CLK2 becomes the fine phase difference or less.

As the fine lock signal FI_LOCK is activated at timing t2 as described above, the size adjustment unit 15 may deactivate the operation enable signal OP_EN to a logic low level. In this case, the reason why the size adjustment unit 15 deactivates the operation enable signal OP_EN to a logic low level in response to the activation of the fine lock signal FI_LOCK is for disabling operations of components, that is, the first comparison unit 22 and the second comparison unit 23, which may consume power within the size adjustment unit 15 regardless of a difference between the phases of the first clock CLK1 and the second clock CLK2. That is, when the fine lock signal FI_LOCK is activated at timing t2, there is no possibility that the level of the control voltage CONV may become higher than the first level or become less than the second level again. Accordingly, it is possible to prevent unnecessary power from being consumed because the size adjustment unit 15 deactivates the operation enable signal OP_EN to a logic low level.

Furthermore, referring to FIG. 6C, an operation of the size adjustment unit 15 when the control voltage CONV is in the state (CONV<VREF2) in which the level of the control voltage CONV is less than the second level after the coarse lock signal CO_LOCK is activated may be seen.

Specifically, when an operation of the phase-locked loop is started, the first clock CLK1 and the second clock CLK2 may be in the state in which a difference between the phases of the first clock CLK1 and the second clock CLK2 is great. In such a state, as the phase detection unit 11, the charge pumping unit 12, the voltage generation unit 13, and the oscillating unit 14 repeatedly operate, the rise and fall of the level of the control voltage CONV may be greatly repeated.

The lock detection unit 16 may maintain both the coarse lock signal CO_LOCK and the fine lock signal FI_LOCK in the deactivation state because the first clock CLK1 and the second clock CLK2 are in the state in which the difference between the phases of the first clock CLK1 and the second clock CLK2 is greater than the coarse phase difference during the interval in which the rise and fall of the level of the control voltage CONV is greatly repeated as described above.

Thereafter, as the operation of the phase-locked loop proceeds, the difference between the phases of the first clock CLK1 and the second clock CLK2 is slowly narrowed, but the control voltage CONV may be in the state (CONV<VREF2) in which the level of the control voltage CONV is less than the second level as the rise of the level of the control voltage CONV is greater than the fall of the level of the control voltage CONV. Next, at timing t1, the coarse lock signal CO_LOCK may be activated as the difference between the phases of the first clock CLK1 and the second clock CLK2 becomes the coarse phase difference or less.

At timing t1 at which the coarse lock signal CO_LOCK has been activated, the size adjustment unit 15 may perform an operation of activating the operation enable signal OP_EN to a logic high level.

Furthermore, the size adjustment unit 15 may activate the second comparison signal COMP2 to a logic high level for the first time and activate the up signal VUP to a logic high level for the first time, at the stat timing of an interval t3 that is slightly later than timing t1 because the control voltage CONV is in the state (CONV<VREF2) in which the level of the control voltage CONV is less than the second level after timing t1.

Furthermore, as the up signal VUP is activated to a logic high level by the size adjustment unit 15, the level of the control voltage CONV may greatly rise, and the control voltage CONV may instantly become the state (CONV≥VREF2) in which the level of the control voltage CONV is the second level or more.

The size adjustment unit 15 may instantly deactivate the second comparison signal COMP2 to a logic low level during the interval t3 because the control voltage CONV is in the state (CONV≥VREF2) in which the level of the control voltage CONV is the second level or more, even for a moment.

Furthermore, the difference between the phases of the first clock CLK1 and the second clock CLK2 may be greater than the coarse phase difference as the control voltage CONV becomes the state (CONV≥VREF2) in which the level of the control voltage CONV is the second level or more even for a moment. The lock detection unit 16 may deactivate the coarse lock signal CO_LOCK to a logic low level again during the interval t3, and may continuously maintain the coarse lock signal CO_LOCK in the deactivation state up to timing t4.

However, the size adjustment unit 15 can prevent the second comparison signal COMP2, which has been instantly deactivated to a logic low level during the interval t3, and the coarse lock signal CO_LOCK, which has been deactivated to a logic low level during the interval t3 and maintains the deactivation state up to timing t4, from affecting whether to activate the up signal VUP. That is, the size adjustment unit 15 may control the coarse lock signal CO_LOCK, which has been activated for the first time at the start timing of the interval t3, to continuously maintain the state in which the up signal VUP has been activated to a logic high level, separately from the operation of instantly deactivating the second comparison signal COMP2 to a logic low level during the interval t3 and the operation of the coarse lock signal CO_LOCK being deactivated to a logic low level during the interval t3 and maintaining the deactivation state up to timing t4.

As the up signal VUP continuously maintains the state in which the up signal VUP has been activated to a logic high level and the control voltage CONV maintains the state (CONV≥VREF2) in which the level of the control voltage CONV is the second level or more as described above, the difference between the phases of the first clock CLK1 and the second clock CLK2 may be gradually narrowed. Next, at timing t2, the fine lock signal FI_LOCK may be activated as the difference between the phases of the first clock CLK1 and the second clock CLK2 becomes the fine phase difference or less.

As the fine lock signal FI_LOCK is activated at timing t2 as described above, the size adjustment unit 15 may deactivate the operation enable signal OP_EN to a logic low level. In this case, the size adjustment unit 15 may deactivate the operation enable signal OP_EN to a logic low level in response to the activation of the fine lock signal FI_LOCK and thereby disable operations of components, that is, the first comparison unit 22 and the second comparison unit 23, which may consume power within the size adjustment unit 15 regardless of a difference between the phases of the first clock CLK1 and the second clock CLK2. That is, when the fine lock signal FI_LOCK is activated at timing t2, there is no possibility that the level of the control voltage CONV may become higher than the first level or less than the second level again. The disclosed embodiments prevent unnecessary power from being consumed because the size adjustment unit 15 deactivates the operation enable signal OP_EN to a logic low level.

It may be evident to a person having ordinary knowledge in the art to which the present disclosure pertains that the present disclosure described above is not limited by the aforementioned embodiments and the accompanying drawings and may be substituted, modified, and changed in various ways without departing from the technical spirit of the present disclosure.

For example, the locations and types of the logic gates and the transistors illustrated in the aforementioned embodiments have to be differently implemented depending on the polarity of an input signal.

What is claimed is:

1. A phase-locked loop comprising:
a phase detection circuit configured to detect a difference between phases of a first clock and a second clock;
a charge pumping circuit configured to perform a charge pumping operation based on an output signal of the phase detection circuit to generate a control voltage;
a voltage generation circuit configured to buffer the control voltage to generate an operating voltage, and configured to vary a level of the operating voltage in proportion to changes in a level of the control voltage and an amount of a control current;
an oscillating circuit configured to generate the second clock that toggles at a frequency corresponding to the level of the operating voltage; and
a size adjustment circuit configured to adjust the amount of the control current to maintain the level of the control voltage within a range between a set first level and a set second level.

2. The phase-locked loop of claim 1, further comprising a lock detection circuit configured to, in response to the output signal of the phase detection circuit, activate a coarse lock signal when the difference between the phases of the first clock and the second clock is detected as being a coarse phase difference or less, and configured to activate a fine lock signal when the difference between the phases of the first clock and the second clock is detected as being a fine phase difference or less, the fine phase difference being smaller than the coarse phase difference,
wherein the size adjustment circuit is enabled when the coarse lock signal is activated and is disabled when the fine lock signal is activated.

3. The phase-locked loop of claim 2, wherein the size adjustment circuit comprises:
an operation controller configured to generate an operation enable signal that is activated in response to the coarse lock signal being activated and that is deactivated in response to the fine lock signal being activated;
a first comparison circuit configured to compare, during an interval in which the operation enable signal is activated, the level of the control voltage with a first reference voltage having a level set as the first level to generate a first comparison signal;
a second comparison circuit configured to compare, during the interval in which the operation enable signal is activated, the level of the control voltage with a second reference voltage having a level set as the second level to generate a second comparison signal; and
a signal generation circuit configured to control whether to activate a down signal in response to the first comparison signal, and configured to control whether to activate an up signal in response to the second comparison signal.

4. The phase-locked loop of claim 3, wherein the voltage generation circuit comprises:
a buffer amplification circuit configured to adjust a level of an output voltage in response to a difference between the level of the control voltage and a level of a feedback voltage;
a current adjustment circuit configured to adjust the amount of the control current that is supplied to an output node of the buffer amplification circuit, in response to an output voltage of the buffer amplification circuit, the down signal, and the up signal;
a distribution circuit configured to distribute a voltage loaded onto the output node of the buffer amplification circuit to generate the feedback voltage; and
an operation voltage generation circuit connected to the output node of the buffer amplification circuit in a current mirror form to generate the operating voltage.

5. The phase-locked loop of claim 4, wherein the current adjustment circuit comprises:
a first adjustment circuit configured to adjust an amount of a first current that flows from a terminal for a source voltage to the output node of the buffer amplification circuit, in response to the output voltage of the buffer amplification circuit;
a second adjustment circuit configured to adjust an amount of a second current that flows from the terminal for the source voltage to the output node of the buffer amplification circuit, in response to the output voltage of the buffer amplification circuit and the down signal; and
a third adjustment circuit configured to adjust an amount of a third current that flows from the terminal for the source voltage to the output node of the buffer amplification circuit, in response to the output voltage of the buffer amplification circuit and the up signal.

6. The phase-locked loop of claim 3, wherein the operation controller comprises:
a first activation controller configured to activate the operation enable signal in response to the coarse lock signal being activated for a first time, and configured to then maintain the operation enable signal in an activation state regardless of whether the coarse lock signal is activated; and
a deactivation controller configured to deactivate the operation enable signal in response to the fine lock signal being activated.

7. The phase-locked loop of claim 6, wherein the signal generation circuit comprises:
a second activation controller configured to activate the down signal in response to the first comparison signal being activated for a first time based on a level of the control voltage, which is higher than the first level, and configured to then maintain the down signal in the activation state regardless of whether the first comparison signal is activated; and
a third activation controller configured to activate the up signal in response to the second comparison signal being activated for a first time based on a level of the control voltage, which is less than the second level, and configured to then maintain the up signal in the activation state regardless of whether the second comparison signal is activated.

8. The phase-locked loop of claim 7, wherein:
the operation controller further comprises a first reset circuit configured to reset the operation enable signal to a deactivation state in response to a reset signal; and
the signal generation circuit further comprises a second reset circuit configured to reset the up signal and the down signal to the deactivation state in response to the reset signal.

9. The phase-locked loop of claim 2, wherein the size adjustment circuit is configured to:
change the amount of the control current in a down fluctuation relatively smaller than a default fluctuation during an interval in which the level of the control voltage is higher than the first level;
change the amount of the control current in the default fluctuation during an interval in which the level of the control voltage is the first level or less and the second level or more; and
change the amount of the control current in an up fluctuation relatively greater than the default fluctuation during an interval in which the level of the control voltage is less than the second level.

10. The phase-locked loop of claim 9, wherein the size adjustment circuit is configured to:
set the amount of the control current to vary in the down fluctuation in response to the level of the control voltage being placed in the interval in which the level of the control voltage is higher than the first level for a first time, and
then maintain a state in which the amount of the control current is set to vary in the down fluctuation until the size adjustment circuit is reset.

11. The phase-locked loop of claim 10, wherein the size adjustment circuit is configured to:
set the amount of the control current to vary in the up fluctuation in response to the level of the control voltage being placed in the interval in which the level of the control voltage is less than the second level for a first time, and
then maintain a state in which the amount of the control current is set to vary in the up fluctuation until the size adjustment circuit is reset.

12. An operating method of a phase-locked loop, the operating method comprising:
detecting a difference between phases of a first clock and a second clock to generate a detection signal;
performing a charge pumping operation in response to the detection signal to generate a control voltage;
generating an operating voltage having a level that varies in proportion to changes in a level of the control voltage and an amount of a control current;
generating the second clock that toggles at a frequency corresponding to the level of the operating voltage; and
adjusting the amount of the control current to maintain the level of the control voltage within a range between a set first level and a set second level.

13. The operating method of claim 12, further comprising:
outputting a coarse lock signal being activated in response to the detection signal indicating that the difference between the phases of the first clock and the second clock is detected as being a coarse phase difference or less;
outputting a fine lock signal being activated in response to the detection signal indicating that the difference between the phases of the first clock and the second clock is detected as being a fine phase difference or less, the fine phase difference being smaller than the coarse phase difference; and
enabling the adjusting of the amount of the control current in response to the coarse lock signal being activated, and disabling the adjusting of the amount of the control current in response to the fine lock signal being activated.

14. The operating method of claim 13, wherein the adjusting of the amount of the control current comprises:
changing the amount of the control current in a down fluctuation relatively smaller than a default fluctuation during an interval in which the level of the control voltage is higher than the first level;
changing the amount of the control current in the default fluctuation during an interval in which the level of the control voltage is the first level or less the second level or more; and
changing the amount of the control current in an up fluctuation relatively greater than the default fluctuation during an interval in which the level of the control voltage is less than the second level.

15. The operating method of claim 14, wherein the changing of the amount of the control current in the down fluctuation comprises:
setting the amount of the control current to vary in the down fluctuation, in response to the level of the control voltage being placed in the interval the level of the control voltage is higher than the first level for a first time; and
then maintaining a state in which the amount of the control current is set to vary in the down fluctuation until the amount of the control current is reset.

16. The operating method of claim 15, wherein the changing of the amount of the control current in the up fluctuation comprises:
setting the amount of the control current to vary in the up fluctuation, in response to the level of the control voltage being placed in the interval in which the level of the control voltage is less than the second level for a first time; and
then maintaining a state in which the amount of the control current is set to vary in the up fluctuation until the amount of the control current is reset.
